(19) United States
(12) Patent Application Publication
(10) Pub. No.: US 2008/0186793 A1
(43) Pub. Date: Aug. 7, 2008

(54) Method and Circuit for Saving Power

(75) Inventors: Jozef Pieter Van Gassel, Eindhoven (NL); Hendrikus Bernardus Van Den Brink, Eindhoven (NL); Artur Burchard, Eindhoven (NL); Steven Broelis Luitjens, Eindhoven (NL); Ozcan Mesut, Eindhoven (NL); Siarhei Yermalayeu, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/576,697

(22) PCT Filed: Oct. 3, 2005
(86) PCT No.: PCT/IB05/53239

§ 371 Date: Apr. 5, 2007

(30) Foreign Application Priority Data
Oct. 8, 2004 (EP) 04104925.5

(51) Int. Cl. G11C 14/00

(52) U.S. Cl. 365/227

(57) ABSTRACT

Portable devices are usually synchronized with servers like personal computers. Furthermore, most portable devices provide a user with the possibility to generate data objects or to obtain data objects from other sources than the personal computer. This means that of certain data objects a backup exists, as they are stored on the personal computer. Other data objects are unique, as the user does not have a backup at his or her disposal. Energy is a precious commodity in portable devices. A memory, in particular a volatile memory, consumes power. In case energy is required for keeping data objects stored, of which no backup is at the disposal of the user, but this energy might not be available in the future due to battery level, storage of data objects of which a backup exists is sacrificed for the benefit of storage of data objects for which there is no backup.

The invention relates to a method of saving power used by a memory.

The invention further relates to a circuit for storing data objects in a memory.

The invention also relates to a computer program product for programming the central processing unit of a computer to let the computer execute such method. The invention yet further relates to a record carrier having stored thereon such computer program product.

The invention again further relates to a programmed computer programmed to execute such method.

Publication US 2003/0053361 discloses a method for selectively refreshing elements of a memory array in response to signals from a conventional memory management system. In an illustrative application, the memory is a dynamic random access memory and the inventive system is adapted to provide for selective refresh of those DRAM memory elements to which data has been or will be stored. This means that all cells where data is or will be stored, are refreshed, which means that all those cells will consume energy.

Publication US 2004/0056067 discloses a method of managing data in memory for reducing power consumption. When power must be saved, a working part of an SDRAM memory is not refreshed and only the banks in which data to be stored for a longer time is refreshed, to keep said data. This means that all data objects not directly related to data processing as such are kept and that energy is spent for keeping these data objects.

It is an object of the invention to further reduce power consumption of the memory. To achieve this object, the invention provides in a first aspect Method of saving power used by a memory comprising at least two compartments, comprising: determining whether a data object to store in the memory is a unique data object, not received from a remote server, or a secured data object received from a remote server; when the data object is a unique data object, storing the data object in a first compartment of the memory; when the data object is a secured data object, storing the data object in a second compartment of the memory; and when a power save trigger is received, reducing power consumption of the second compartment.

The unique data objects are by far the most important to keep stored. When energy is needed for this, it is important that enough energy is available. This may even require that storage of certain data objects is sacrificed to save energy to keep unique data objects. When of other data objects—the secured data objects—a copy is available for a user—at the server—it may not be problem when they are temporarily lost on another device. They can be recovered by downloading them again from the server.

In an embodiment of the method according to the invention, a unique data object is considered a secured data object when a different version of the data object exists. In an embodiment of the invention, the objects exists on the server. In what way the versions differ is not immediately relevant; the most important is that the data object can be discarded to save further energy.

In a second aspect, the invention provides a circuit for storing data objects in a memory, the circuit comprising a memory having two compartments; a power control unit for generating a power trigger; a processor for controlling the circuit; wherein the processor is conceived to: determine whether a data object to store in the memory is a unique data object, not received from a remote server, or a secured data object received from a remote server; when the data object is a unique data object, store the data object in a first compartment of the memory; when the data object is a secured data object, store the data object in a second compartment of the memory; and when a power save trigger is received, reduce power consumption of the second compartment.

In a third aspect, the invention provides a computer program product for programming the central processing unit of a computer to let the computer execute the method according to the invention.

In a fourth aspect, the invention provides a record carrier having stored thereon such computer program product.

In a fifth aspect, the invention provides a programmed computer programmed to execute the method according to the invention.

These and other aspects of the invention are described by means of Figures, It is stipulated that the description of the preferred embodiments of the invention merely serves as to illustrate the invention and do not limit the scope of the invention. In the Figures,

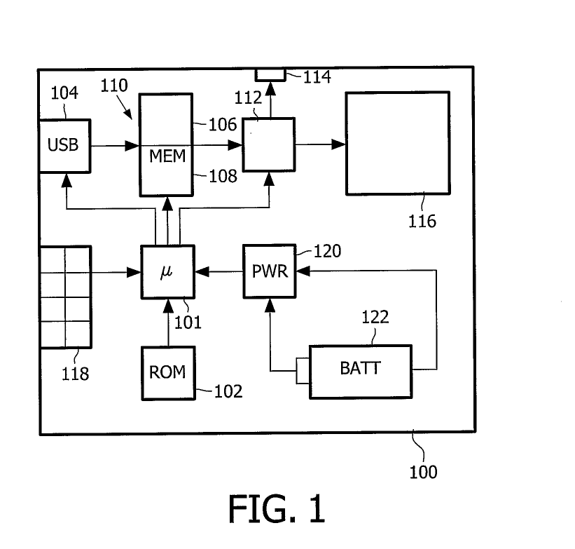

FIG. 1 shows an embodiment of the apparatus according to the invention; and

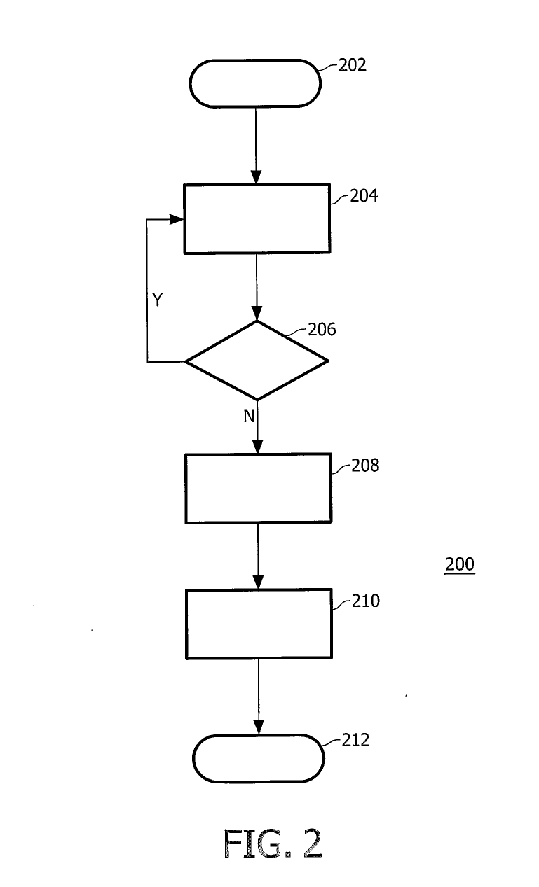

FIG. 2 shows a flowchart depicting an embodiment of the method according to the invention.

FIG. 1 shows a portable consumer device 100 as an embodiment of the apparatus according to the invention. The portable consumer device 100 comprises a program code memory 102, a communication unit 104, a memory 110 comprising a first memory compartment 106 and a second memory compartment 108, a multimedia processor 112 for decoding and rendering audiovisual data objects, a headphone jack 114, a display 116, a user input unit 118, a battery control unit 120, a battery 122 and a central processing unit 101 for controlling the operations of the portable consumer device 100. In another embodiment of the invention, the program code memory 102 and central processing unit are replaced by an application specific integrated circuit also known as ASIC as processing unit to control the portable consumer device 100.

In an embodiment of the invention, the communication unit 104 is a USB 2.0 socket and controller for receiving data objects from and sending data objects to a remote server like a personal computer. In a preferred embodiment, a data object comprises audiovisual data like audio and video streams and still images. When the data object is received from the personal computer, it is saved in the second memory compartment 108 of the memory 110. In the embodiment currently being described, the memory 110 is implemented as a dynamic random access memory, DRAM.

When a user intends to have audiovisual data stored in the memory 110 reproduced, the user commands the portable consumer device 100 to do so by means pressing a ‘play’ button on the user input unit 118. This generates an electrical signal in the user input unit 118 that is transferred to the central processing unit 101 that controls the multimedia processor 112 to retrieve a selected object from the memory, render it and send it for output to the headphone 114—to which headphones are connectable—and/or to the display 116 for reproduction.

In this embodiment, the instructions for the operations of the central processing unit are controlled by a computer program product stored in the program code memory 102. The program code memory 102 can be embodied as a CD-ROM, a ROM integrated circuit, a harddisk, a Flash memory or any other type of memory.

A user is also enabled to create his or her own data objects on the portable consumer device 100 by means of the user input unit 104. To this, the user input unit 118 comprises in this embodiment a microphone, a camera, buttons for editing audiovisual data objects, with or without visual aids like a graphical user interface (GUI) on the display 116. The data object created in this way is stored in the first memory compartment 106 of the memory 110.

Such a data object is de facto not backed up or stored on the remote server and is therefore for this embodiment called a unique data object. This means that in case the memory 110 is a volatile memory like DRAM or SRAM and the power in the portable consumer device 100 is gone or low because the battery 122 is empty or nearly empty, all data objects are lost. For the data objects that is stored on the remote server, this is no problem, as it can be re-downloaded to the portable consumer device 100. These data objects are referred to as secured data objects.

To keep the unique data objects, the secured data objects are sacrificed in the portable consumer device 100, by shutting down the power supply of the second memory compartment 108. In this way, power that would otherwise be used for keeping the secured data stored, can now be used to extend the time that unique data is stored in the portable consumer device 100.

This process is elucidated by a flowchart 200 in FIG. 2, depicting an embodiment of the method according to the invention. The names of the processes in the blocks are provided in Table 1.

TABLE 1

| Reference numeral | Process |
|---|---|
| 202 | Content stored |
| 204 | Normal operation |
| 206 | Battery level OK? |
| 208 | Reduce power of second memory compartment |
| 210 | Issue user warning |
| 212 | Continue operation |

The process starts in a process start step 202 in which the status is that data objects are stored in the memory 110, unique data objects in the first memory compartment 106 and secured data objects in the second memory compartment 108. From this point, the portable consumer device 100 continues with normal operation in a process step 204. During this operation, the battery control unit 120 controls the level of energy in the battery 122. When the battery level is good, the portable consumer device 100 continues in normal operation in the process step 204.

When the battery level is low and data storage in the memory 110 cannot be guaranteed for a very long time anymore—this can be hours or a few days, depending on the way the invention is embodied—the process branches to a process step 208 in which the power consumption of the second memory compartment 108 is reduced. This can be embodied in various ways. First, the second memory compartment 108 can be powered off. This results in loss of all data objects stored in the second memory compartment 108. Second, it can be disallowed to read any data objects from the second memory compartment 108 or the whole of the memory 106. Reading data objects costs more power than merely keeping (in case of a DRAM, refreshing) the data objects, so power can also be reduced in this way. Third, in the case wherein the second memory compartment is embodied as a DRAM, the refresh rate of the memory can be lowered. A combination of the third and second embodiment mentioned here is also possible. Furthermore, also other embodiments are known by a person skilled in the art.

Subsequently, this embodiment provides that a warning is issued to the user in a process step 210. This can be a warning that secured data objects are not accessible anymore or that they are lost. Meanwhile, the operation of the portable consumer device 100 is continued in the terminator 212.

In case the portable consumer device 100 really runs out of power now, also the unique data objects are lost, of course. However, this loss of unique data is postponed by the method according to the invention.

Up to this point in the description of embodiment of the various aspects of the invention, unique data objects have been described as data objects created on or by the portable consumer device 100. However, unique data may also be data that is obtained from other users. In a very general sense of the word, unique data is data that was not in possession of the user and was obtained by means of the portable consumer device 100.

Secured data, up till now, has been described as data being available on a remote server like a personal computer. Then again, data may also be secure when two versions of a data object exist on the portable consumer device 100, one in the first memory compartment 106 and one in the second memory compartment 108. The difference between the two versions may be the age—the newest version comprises bug fixes—or the quality—one version has a higher quality. Preferably, the newest data object and/or the data object with the highest quality are stored in the first memory compartment 106. In other embodiments, this is the other way around. For data streams, in particular comprising audiovisual data, the quality can be determined by the bitrate of the stream. For still image picture, the quality can be determined by the pixel density.

As a person skilled in the art will readily appreciate, the other version of the data object may also exist on the remote server. When this is the case, a data object on the portable consumer device 100 may also be considered secure in one embodiment. In other embodiments, this is only the case when the version on the remote server is newer (or older) or has a higher (or lower) quality. The implementation of the various criteria is irrelevant for the scope of the invention.

When data is transferred to the portable consumer device 100 by means of the communication unit 104, it may be stored in a so-called vault. When data is in this vault, it is not accessible by any user using the remote server. In one embodiment of the invention, data stored in the memory 110 of the portable consumer device 100 is only considered secure when data is in the so-called vault. The privileges for using data in the vault are irrelevant for the scope of the invention.

It may also be that a user on the remote server can only read the files, read and modify the files or even delete the files, although the latter option is not a preferred embodiment. It may even be that the event of deletion of a file on the remote server is communicated to the portable consumer device 100 and the file on the portable consumer device 100 is marked as unique and moved to the first memory compartment 106.

The invention is in particular suitable for volatile memories, but also non-volatile memories consume power, e.g. in a standby mode. Power can be saved by completely switching off the memory.

The invention can be embodied in a wide range of devices, portable and stationary, audio and video players and recorders, personal digital assistants, laptop computers, portable databanks and a wide range of other devices.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

Furthermore, the invention may also be embodied with less components than provided in the embodiments described here, wherein one component carries out multiple functions. Just as well may the invention be embodied using more elements than depicted in FIG. 1, wherein functions carried out by one component in the embodiment provided are distributed over multiple components.

It is stipulated that the reference signs in the claims do not limit the scope of the claims, but are merely inserted to enhance the legibility of the claims.

In summary, the invention relates to the following:

Portable devices are usually synchronized with servers like personal computers. Furthermore, most portable devices provide a user with the possibility to generate data objects or to obtain data objects from other sources than the personal computer. This means that of certain data objects a backup exists, as they are stored on the personal computer. Other data objects are unique, as the user does not have a backup at his or her disposal. Energy is a precious commodity in portable devices. A memory, in particular a volatile memory, consumes power. In case energy is required for keeping data objects stored, of which no backup is at the disposal of the user, but this energy might not be available in the future due to battery level, storage of data objects of which a backup exists is sacrificed for the benefit of storage of data objects for which there is no backup.

1. Method of saving power used by a memory comprising at least two compartments, comprising:
a) determining whether a data object to store in the memory is a unique data object, not received from a remote server, or a secured data object received from a remote server;
b) when the data object is a unique data object, storing the data object in a first compartment of the memory;
c) when the data object is a secured data object, storing the data object in a second compartment of the memory; and
d) when a power save trigger is received, reducing power consumption of the second compartment.

2. Method as claimed in claim 1, wherein the reducing of the power consumption of the second compartment comprises switching off the second compartment.

3. Method as claimed in claim 1, wherein the memory is a dynamic memory and reducing of the power consumption of the second compartment comprises no more refreshing the second compartment.

4. Method as claimed in claim 1, wherein a unique data object is considered a secured data object when a different version of the data object exists.

5. Method as claimed in claim 4, wherein the different version of the data object exists on the server.

6. Method as claimed in claim 4, wherein the different version of the data object is a version of the data object with another quality

7. Method as claimed in claim 6, wherein the data object is a stream of audiovisual data and quality is determined by the bit rate.

8. Method as claimed in claim 6, wherein the data object is a still image picture and the quality is determined by the pixel density.

9. Method as claimed in claim 1, wherein data received from a remote server is only considered unique when the content is locked for modification and deletion on the remote server.

10. Method as claimed in claim 1, wherein memory is powered by a battery and the power save trigger is generated in response to a low battery level.

11. Circuit for storing data objects in a memory, the circuit comprising
a) a memory having two compartments;
b) a power control unit for generating a power trigger;
c) a processor for controlling the circuit;
wherein the processor is conceived to:
d) determine whether a data object to store in the memory is a unique data object, not received from a remote server, or a secured data object received from a remote server;
e) when the data object is a unique data object, store the data object in a first compartment of the memory;
f) when the data object is a secured data object, store the data object in a second compartment of the memory; and
g) when a power save trigger is received, reduce power consumption of the second compartment.

12. Circuit as claimed in claim 11, wherein the memory is a volatile memory.

13. Apparatus for storing data objects, comprising:
a) a communication unit for receiving data objects;
b) a data generation unit for generating data objects;
c) a rendering unit for rendering data objects; and
d) the circuit as claimed in claim 9.

14. Computer program product for programming the central processing unit of a computer to let the computer execute the method according to claim 1.

15. Record carrier having stored thereon the computer program product as claimed in claim 14.

16. Programmed computer programmed to execute the method as claimed in claim 1.
